(19) United States
(12) Patent Application Publication
(10) Pub. No.: US 2013/0200432 A1
(43) Pub. Date: Aug. 8, 2013

(54) SEMICONDUCTOR COMPONENT, SUBSTRATE AND METHOD FOR PRODUCING A SEMICONDUCTOR LAYER SEQUENCE

(71) Applicants: Peter Stauß, Regensburg (DE); Patrick Rode, Regensburg (DE); Philipp Drechsel, Mintraching (DE)

(72) Inventors: Peter Stauß, Regensburg (DE); Patrick Rode, Regensburg (DE); Philipp Drechsel, Mintraching (DE)

(73) Assignee: OSRAM Opto Semiconductors GmbH, Regensburg (DE)

(21) Appl. No.: 13/809,642

(22) PCT Filed: Jul. 7, 2011
(86) PCT No.: PCT/EP2011/061523

§ 371 Date: Feb. 11, 2013

(30) Foreign Application Priority Data
Jul. 15, 2010 (DE) 10 2010 027 411.9

(51) Int. Cl. H01L 21/36; H01L 29/267

(52) U.S. Cl. CPC H01L 21/36; H01L 29/267
USPC 257/183; 438/478

(57) ABSTRACT

A semiconductor component includes a semiconductor body based on a nitride compound semiconductor material, and a substrate on which the semiconductor body is arranged, wherein impurities are formed in the substrate in a targeted manner.

### RELATED APPLICATIONS

This is a §371 of International Application No. PCT/EP2011/061523, with an international filing date of Jul. 7, 2011 (WO 2012/007350 A1, published Jan. 19, 2012), which is based on German Patent Application No. 10 2010 027 411.9, filed Jul. 15, 2010, the subject matter of which is incorporated herein by reference.

### TECHNICAL FIELD

This disclosure relates to a semiconductor component, a substrate for the production of a semiconductor component, and a method for producing a semiconductor layer sequence for a semiconductor component.

### BACKGROUND

During epitaxial deposition of nitridic compound semiconductor material on a growth substrate, a strain of the deposited semiconductor layers relative to the growth substrate can lead to warpage of the growth substrate. Such warpage can have the effect that the growth substrate no longer bears on the substrate holder over the whole area, as a result of which thermal linking to the substrate holder is impaired. This can cause an inhomogeneous deposition of the semiconductor layers.

It could therefore be helpful to provide a semiconductor component which can be produced reliably and in a simplified manner, as well as to provide a substrate and a method with which semiconductor layers can be deposited homogeneously and reliably.

### SUMMARY

We provide a semiconductor component including a semiconductor body based on a nitridic compound semiconductor material, and a substrate on which the semiconductor body is arranged, wherein impurities are formed in the substrate in a targeted manner.

We also provide a substrate for deposition of nitridic compound semiconductor material, wherein impurities that increase its upper yield point are formed in a targeted manner in the substrate.

We further provide a method for producing a semiconductor layer sequence based on a nitridic compound semiconductor material including depositing the semiconductor layer sequence on a substrate, in which impurities are formed in a targeted manner.

We still further provide a method for producing a semiconductor layer sequence based on a nitridic compound semiconductor material including depositing the semiconductor layer sequence on a substrate, wherein impurities are formed in a targeted manner, and the substrate is removed or thinned at least in regions after deposition of the semiconductor layer sequence.

### BRIEF DESCRIPTION OF THE DRAWINGS

FIG. 1 shows a first example of a semiconductor component in schematic sectional view.

FIGS. 2A to 2D show a first example of a method for producing a semiconductor component on the basis of intermediate steps respectively illustrated in schematic sectional view.

FIGS. 3A to 3D show a second example of a method for producing a semiconductor component on the basis of intermediate steps respectively illustrated in schematic sectional view.

FIG. 4 shows results of a measurement of the curvature C for different substrates as a function of the deposition duration t.

### DETAILED DESCRIPTION

We provide a semiconductor component that may comprise a semiconductor body based on a nitridic compound semiconductor material and a substrate on which the semiconductor body is arranged. Impurities are formed in a targeted manner in the substrate.

In a method for producing a semiconductor layer sequence on the basis of a nitridic compound semiconductor material, the semiconductor layer sequence may be deposited on a substrate, wherein impurities are formed in a targeted manner in the substrate. To produce semiconductor components, semiconductor bodies for semiconductor components can emerge from the semiconductor layer sequence by singulation.

In the present context “based on nitridic compound semiconductors” means that the active epitaxial layer sequence or at least one layer thereof comprises a nitride III/V compound semiconductor material, preferably AlₙGaₘIn₁₋ₙ₋ₘN, wherein 0≦n≦1, 0≦m≦1 and n+m≦1. In those cases, this material need not necessarily have a mathematically exact composition according to the above formula. Rather, it can comprise one or more dopants and additional constituents which substantially do not change the characteristic physical properties of the AlₙGaₘIn₁₋ₙ₋ₘN material. For the sake of simplicity, however, the above formula includes only the essential constituents of the crystal lattice (Al, Ga, In, N), even if these can be replaced in part by small amounts of further substances.

An “impurity” means that the substrate is pervaded at least in regions with foreign atoms composed of a material different than a basic material of the substrate. The foreign atoms can be incorporated, for example, at lattice sites of the substrate crystal or between adjacent lattice sites.

A “targeted impurity” means, in particular, that the impurities are introduced in a defined manner during production of the substrate, for example, by targeted provision of the material for the impurities. In contrast, a substrate which is optimized toward as little contamination as possible during manufacture and contains merely in a manner governed by manufacture residues of a foreign material that cannot completely be avoided is not regarded as incorporating impurities in a targeted manner.

The impurities are provided in particular to increase the upper yield point of the substrate. Plastic deformation occurs above the upper yield point. Therefore, the upper yield point represents a transition from an elastic region to a plastic region. In particular, the response of a material is no longer proportional to the strain having an effect. The higher the upper yield point, the higher the strain having an effect can be without a plastic deformation occurring.

In contrast to elastic deformation, in the case of a plastic deformation a material no longer returns to its initial state when the strain is removed. In the case of a plastic deformation of a crystal, dislocations can travel in the substrate and/or new dislocations can arise. The relationship between plastic deformation and the movement of dislocations is described in connection with the hardening of metals in the article “Solid Solution Hardening & Strength” in Technical Tidbits, Vol. 2, No. 10 (October 2000), published by Brush Wellman Inc., Cleveland.

The upper yield point can be increased by the impurities such that the strain acting on the substrate during the deposition of the semiconductor layer sequence does not result in any, or at least any significant, plastic deformation. In other words, deposition can be effected in the elastic region of the substrate.

Preferably, impurities are formed such that the substrate withstands a strain acting on the substrate of up to 0.5 GPa, preferably of up to 1.0 GPa, without experiencing plastic deformation. During deposition of semiconductor material, for instance on the basis of nitridic compound semiconductors, the stress acting on the substrate increases as the layer thickness of the semiconductor material increases. Furthermore, the greater the strain, the greater the lattice mismatch between the substrate and the semiconductor material. The higher the upper yield point, the greater the layer thickness can be, therefore, without plastic deformation occurring. In this case, deformation of the substrate is substantially determined by the properties thereof in the elastic region.

We found that, contrary to the basic endeavor to eliminate to the greatest possible extent impurities that reduce crystal quality, reliability of the production method for semiconductor layer sequences for electronic or optoelectronic semiconductor components can be increased by using substrates incorporating impurities in a targeted manner.

In particular, it is possible to produce semiconductor material with a comparatively high thickness, for instance 3 μm or more, with high crystalline quality and homogeneity in a lateral direction, that is to say perpendicular to the deposition direction. The risk of deposition that is inhomogeneous in a lateral direction is reduced on account of the reduced deformation of the substrate and, in particular, a more uniform thermal linking associated therewith.

Furthermore, in the case of a predefined maximum strain acting on the substrate during deposition of the semiconductor layers, the thickness of a substrate having impurities introduced in a targeted manner can be reduced compared to a substrate without such impurities, without the upper yield point being exceeded. Thus, the material requirement can be reduced and production costs can be lowered.

The impurities are expediently formed, in particular with regard to material and concentration such that they increase the upper yield point of the substrate.

Preferably, the impurities are formed at a concentration of 1*10¹⁴ cm⁻³ to 1*10²⁰ cm⁻³ in the substrate. The impurities can be electrically active (that is to say such that they increase the electrical conductivity of the substrate) or electrically inactive. The concentration required for a significant increase in the upper yield point depends in particular on the material of the impurities.

Preferably, the impurities contain carbon, nitrogen, boron or oxygen. Furthermore, the impurities can be formed with at least two of those materials, for example, with oxygen and carbon, or with oxygen and boron. In the case of oxygen, carbon and boron, the concentration of the impurities is preferably 1*10¹⁷ cm⁻³ to 1*10²⁰ cm⁻³, particularly preferably 1*10¹⁸ cm⁻³ to 1*10²⁰ cm⁻³. In the case of nitrogen, the concentration of the impurities is preferably 1*10¹⁴ cm⁻³ to 1*10¹⁶ cm⁻³.

Particularly in the case of a substrate which has a lower coefficient of thermal expansion than the material to be deposited, for example, in the case of a silicon substrate or a silicon carbide substrate, the preferably epitaxial deposition of the nitridic compound semiconductor material is preferably effected such that the semiconductor layer sequence is compressively strained with respect to the substrate at a deposition temperature. That is to say that the compound semiconductor material assumes a lattice constant which, in the lateral plane, is lower than an intrinsic lattice constant of the compound semiconductor material. During cooling of the semiconductor layer sequence, this reduces the risk that the difference in the coefficients of thermal expansion between the semiconductor layer sequence and the substrate will result in disturbances in the semiconductor layer sequence, for example, cracks.

Preferably, the compressive strain is adapted to a difference in the coefficient of thermal expansion between the semiconductor layer sequence and the substrate such that the semiconductor layer sequence is unstrained or at least substantially unstrained at room temperature. Preferably, the strain at room temperature is at most 10%, particularly preferably at most 5%, most preferably at most 1%.

Preferably, the substrate has a silicon surface provided as a deposition plane. The substrate can be in particular a silicon bulk substrate or an SOI (silicon on insulator) substrate.

The silicon surface is furthermore preferably a (111) plane of the substrate. A silicon substrate in this orientation is distinguished by an increased upper yield point relative to other orientations. Furthermore, on account of its six-fold symmetry, a (111) plane is particularly suitable for deposition of nitridic compound semiconductor material.

The semiconductor layer sequence of the semiconductor body of the semiconductor component preferably forms a functional region of the semiconductor component. In other words, the region crucial for functionality of the semiconductor component is formed outside the substrate. Compared with a silicon-based semiconductor component in which the components are typically at least partly integrated into the silicon substrate, this reduces the risk that a reduced crystal quality of the substrate caused by the impurities will impair functionality of the semiconductor component. Therefore, to increase the upper yield point, it is possible to introduce impurities with a comparatively high concentration without this disadvantageously affecting the functionality of the semiconductor component.

The semiconductor body may have an active region provided to generate and/or receive radiation. The active region crucial for the efficiency of the component in the operation thereof is therefore formed outside the substrate.

Alternatively, the semiconductor component may be a, preferably active, electronic semiconductor component, for example, as a transistor for instance as a high electron mobility transistor (HEMT) or as a heterojunction bipolar transistor (HBT).

We found that a substrate in which impurities for increasing the upper yield point of the substrate are formed in a targeted manner is particularly suitable for use as a growth substrate for the deposition of nitridic compound semiconductor material.

However, such a substrate can also be used for deposition of other III-V compound semiconductor materials, for example, on the basis of phosphidic compound semiconductor materials.

In this context, “based on phosphidic compound semiconductors” means that the semiconductor body, in particular the active region, preferably comprises AlₙGaₘIn₁₋ₙ₋ₘP, wherein 0≦n≦1, 0≦m≦1 and n+m≦1, preferably where n≠0 and/or m≠0. In this case, this material need not necessarily have a mathematically exact composition according to the above formula. Rather, it can comprise one or more dopants and additional constituents which substantially do not change the physical properties of the material. For the sake of simplicity, however, the above formula includes only the essential constituents of the crystal lattice (Al, Ga, In, P), even if these can be replaced in part by small amounts of further substances.

After deposition, in particular after cooling to room temperature, the substrate can be removed or thinned at least in regions, for example, mechanically, chemically or by coherent radiation. The semiconductor layer sequence can be fixed to a carrier before the substrate is removed, which in particular mechanically stabilizes the semiconductor layer sequence.

A semiconductor component in which a growth substrate is removed is also designated as a thin-film semiconductor component.

By way of example, a light-emitting diode chip can be a thin-film semiconductor component and can be distinguished in particular by at least one of the following characteristic features:
a reflective layer is applied or formed at a first main area (facing toward a carrier element) of a radiation-generating epitaxial layer sequence, the reflective layer reflecting at least part of the electromagnetic radiation generated in the epitaxial layer sequence back into the latter;
the epitaxial layer sequence has a thickness of 20 μm or less, in particular 10 μm; and
the epitaxial layer sequence contains at least one semiconductor layer having at least one area having an intermixing structure which ideally leads to an approximately ergodic distribution of the light in the epitaxial layer sequence, that is to say that it has an as far as possible ergodically stochastic scattering behavior.

A basic principle of a thin-film light-emitting diode chip is described, for example, in I. Schnitzer et al., Appl. Phys. Lett. 63 (16), Oct. 18, 1993, 2174-2176, the disclosure of which is hereby incorporated by reference.

A thin-film light-emitting diode chip is, to a good approximation, a Lambertian surface emitter and is therefore particularly well suited to application in a headlight.

The method described and the substrate described are particularly suitable for producing the semiconductor component described. Features explained in connection with the semiconductor component can therefore also be used for the method and, respectively, the substrate, and vice versa.

Further features, configurations and expediencies will become apparent from the following description of the examples in conjunction with the Drawings.

Elements that are identical, of identical type or act identically are provided with the same reference signs in the Drawings.

The Drawings and the size relationships of the elements illustrated therein among one another should not be regarded as to scale. Rather, individual elements may be illustrated with an exaggerated size to enable better illustration and/or afford a better understanding.

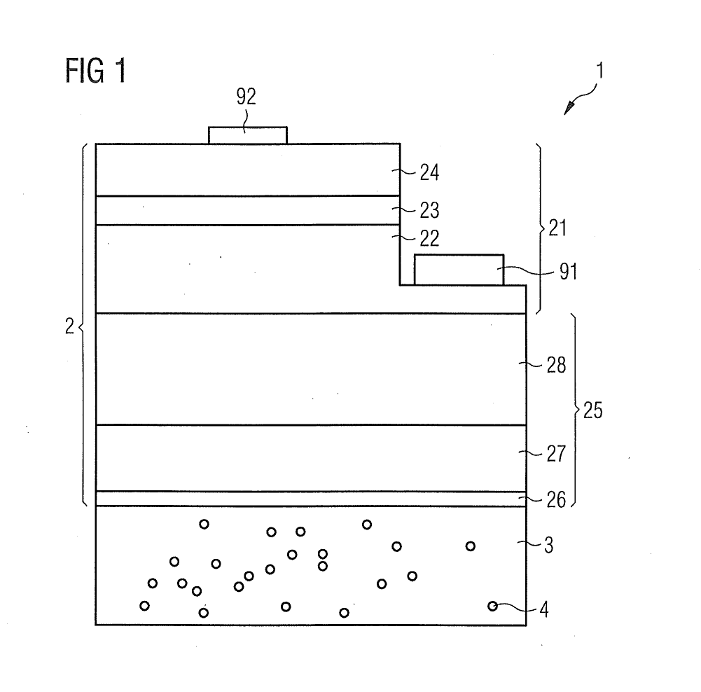

FIG. 1 shows an example of a semiconductor component 1 which is by way of example a thin-film light-emitting diode chip.

The semiconductor component 1 comprises a semiconductor body 2 having a semiconductor layer sequence. The semiconductor layer sequence forming the semiconductor body is preferably deposited epitaxially, for instance by MOVPE or MBE, on a substrate 3.

Impurities 4 are formed in the substrate 3, the impurities arranged at lattice sites or between adjacent lattice sites into the crystal structure of the substrate. In particular, a bulk silicon substrate is suitable as a substrate. However, an SOI substrate can also be used. Preferably, the substrate has a surface in (111) orientation facing the semiconductor body. Silicon has an increased upper yield point in this orientation. Silicon is furthermore distinguished by a high thermal conductivity. Furthermore, silicon substrates, in particular in comparison with other growth substrates for nitridic compound semiconductor material such as sapphire, silicon carbide or gallium nitride, are available with a large area and are cost-effective.

The impurities 4 are preferably introduced into the substrate at a concentration of 1*10¹⁴ cm⁻³ to 1*10²⁰ cm⁻³. The impurities can be electrically active or electrically inactive.

Preferably, the impurities contain carbon, nitrogen, boron or oxygen. In the case of oxygen, carbon and boron the concentration of the impurities is preferably 1*10¹⁷ cm⁻³ to 1*10²⁰ cm⁻³, particularly preferably 1*10¹⁸ cm⁻³ to 1*10²⁰ cm⁻³. In the case of nitrogen, the concentration of the impurities is preferably 1*10¹⁴ cm⁻³ to 1*10¹⁶ cm⁻³. Furthermore, the impurities can be formed with at least two of those materials, for example, with oxygen and carbon, or with oxygen and boron.

What can be achieved with the stated concentrations is that during deposition of the semiconductor layer sequence for the semiconductor body 2, the substrate withstands a strain of at least 0.5 GPa, preferably of at least 1.0 GPa without plastic deformation occurring.

The semiconductor body 2 has an intermediate region 25 adjoining the substrate 3. A component region 21 is formed on that side of the intermediate region which faces away from the substrate.

The semiconductor layers of the semiconductor body 2 are in each case based on AlₙGaₘIn₁₋ₙ₋ₘN, wherein 0≦n≦1, 0≦m≦1 and n+m≦1.

The component region 21 has an active region 23 provided to generate radiation, the active region being arranged between a first semiconductor layer 22 and a second semiconductor layer 24.

During operation of the semiconductor component, via a first contact 91 and a second contact 92 charge carriers can be injected from different sides into the active region 23 and recombine there with the emission of radiation.

The component region 21 preferably has a thickness of 2 μm to 8 μm, particularly preferably 4 μm to 5 μm. Depending on the type of the semiconductor component 1, however, larger or smaller thicknesses can also be expedient.

A Bragg mirror can be formed between the active region 21 and the substrate 3 to avoid absorption of radiation by the substrate 3, in particular on that side of the component region 21 which faces the intermediate region 25, the Bragg mirror reflecting radiation emitted in the direction of the substrate during operation.

The semiconductor layers of the intermediate region 25 predominantly serve to increase the quality of the semiconductor layers of the component region 21 which is crucial for operation.

The intermediate region 25 comprises a nucleation and buffer layer 26, a transition layer 27 and a strain region 28 deposited successively on the substrate.

The nucleation and buffer layer 26 adjoining the substrate 3 is based on AlN. This layer serves for the nucleation of the substrate 3 and has a thickness of 50 nm to 300 nm, for example, 200 nm. The transition layer disposed downstream is based on AlGaN and provided to increase the gallium content, for example, step-by-step or continuously.

The strain region 28 forms a compressive strain at the deposition temperature. During cooling after deposition, the compressive strain can completely or at least partly compensate for the tensile strain caused by the difference in the coefficient of thermal expansion between the substrate and the semiconductor layer sequence of the semiconductor body 2. A GaN layer into which one or more AlGaN layers, for example, two to three AlGaN layers, are embedded is suitable for the strain region. The thickness of the strain region is preferably 2 μm to 3 μm, for example, 2.5 μm.

At room temperature, the strain is preferably at most 10%, particularly preferably at most 5%, most preferably at most 1%.

The intermediate region 25 is largely independent of the downstream component region and can therefore also be employed for other optoelectronic or electronic components.

By way of example, in a departure from the example described, the semiconductor component can also be an electronic semiconductor component, for instance as a semiconductor component for radio-frequency technology or for power electronics. By way of example, the semiconductor component can be a transistor, for instance an HBT or an HEMT. In this case, the component region 21 arranged on the intermediate region 25 has the functional layers characteristic of the respective electronic semiconductor component, for example, the semiconductor layers forming at least one heterojunction in an HBT, or a layer in which a two-dimensional electron gas is formed in the case of an HEMT. The functional layers are therefore formed outside the substrate 3. The impurities 4 can therefore be introduced into the substrate to increase the upper yield point and can thus bring about an improved homogeneity of the deposition of the semiconductor layers without the impurities adversely influencing functionality of the semiconductor components.

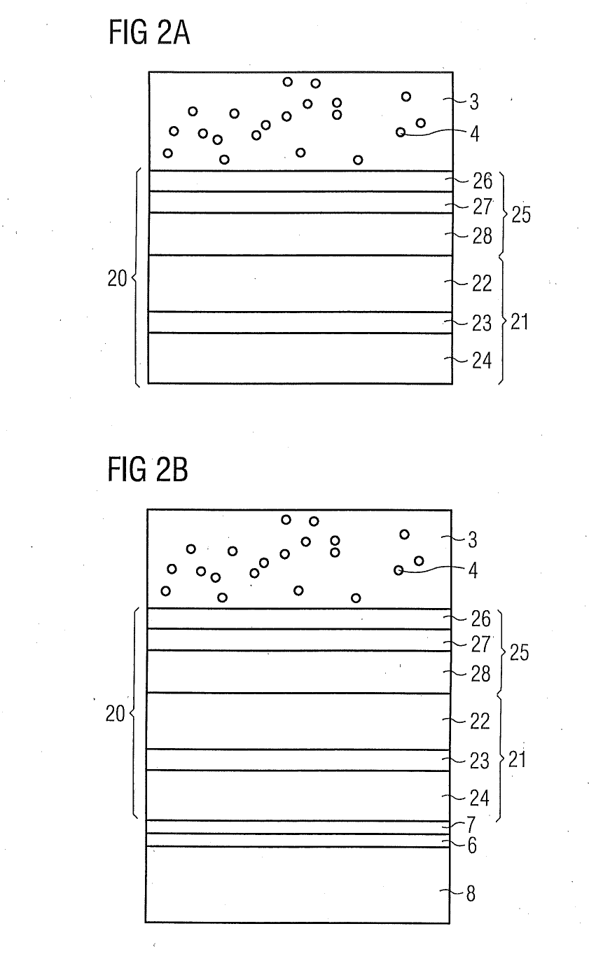

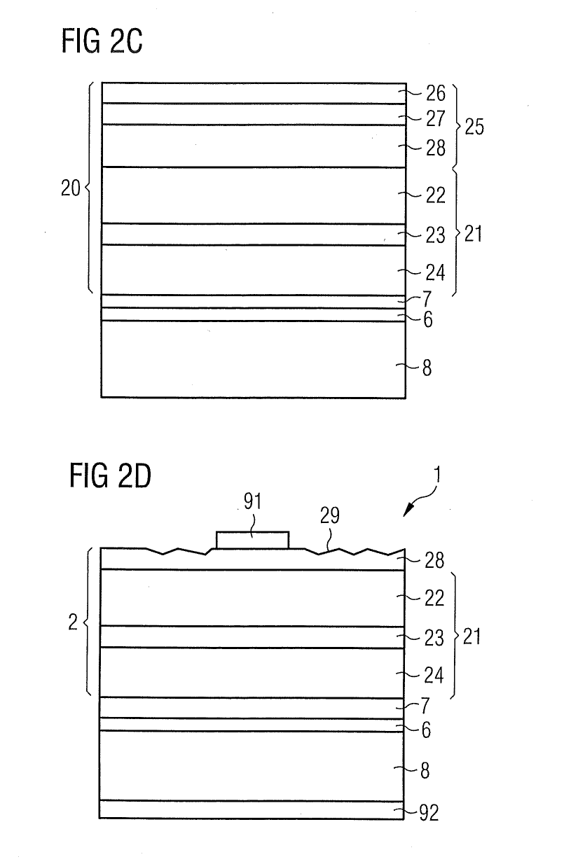

One example of a method for producing a semiconductor layer sequence subsequently processed further into semiconductor components is shown in FIGS. 2A to 2D. The method is described by way of example on the basis of the production of a thin-film light-emitting diode chip, only that region of the semiconductor layer sequence from which a semiconductor body for a semiconductor component emerges being shown for the sake of simplified illustration.

A substrate 3 provided with impurities 4 in a targeted manner is provided as a growth substrate. The substrate can be produced, for example, by a Czochralski method or by a floating zone method.

A substrate 3 produced by the floating zone method can be distinguished by an improved crystal quality. The material provided to form the impurity can be provided during production such that it is incorporated into the crystal of the substrate at the lattice sites or between lattice sites.

A semiconductor layer sequence 20 comprising an intermediate region 25 and a component region 21 is deposited epitaxially on the substrate 3, wherein these regions can be as described in connection with FIG. 1 (FIG. 2A).

The impurities 4 are preferably introduced with a concentration such that deposition of the semiconductor layer sequence takes place in the region of elastic deformation, that is to say below the upper yield point.

Preferably, by the impurities 4, during the deposition, that is to say at temperatures of approximately 1000° C., the substrate withstands a strain of at least 0.5 GPa, particularly preferably at least 1.0 GPa, without experiencing plastic deformation.

After deposition of the semiconductor layer sequence 20, the latter can be processed further into semiconductor components. During production of a thin-film semiconductor chip, the semiconductor layer sequence, as illustrated in FIG. 2B, is fixed to a carrier 8 by a connecting layer 6, for example, solder or an electrically conductive adhesive layer.

The carrier 8 need not fulfill the high crystalline properties imposed on a growth substrate and can be chosen with regard to other properties, for example, with regard to a high thermal conductivity. By way of example, a semiconductor material, for instance silicon, germanium or gallium arsenide, or a ceramic, for instance aluminum nitride or boron nitride, is suitable for the carrier.

Prior to fixing, a mirror layer 7 is formed between the carrier 8 and the semiconductor layer sequence 2. The mirror layer is provided to reflect radiation generated in the active region 23 during operation. The mirror layer preferably contains a metal having a high reflectivity for the radiation generated in the active region, or a metallic alloy. By way of example, aluminum, silver, rhodium, palladium, nickel or chromium is suitable in the visible spectral range.

The carrier 8 mechanically stabilizes the semiconductor layer sequence 20. The substrate 3 is no longer required for this purpose and can be removed, for example, wet-chemically (FIG. 2C). Alternatively or supplementarily, however, a mechanical method, for instance grinding, polishing or lapping, can also be employed.

After removal of the substrate 3, a surface of the semiconductor layer sequence which faces away from the carrier 8 is provided with a structuring 29, for example, a roughening. The coupling-out efficiency for radiation generated in the active region can thus be increased.

Material of the intermediate region 25 is partly removed to form the structuring 29. By way of example, the nucleation and buffer layer 26 and the transition layer 27 can be completely removed such that the structuring 29 can be formed in the strain region 29.

For the injection of charge carriers into the active region 23, a first contact 91 and a second contact 92 are formed, for instance by vapor deposition or sputtering. A completed thin-film semiconductor component is illustrated in FIG. 2D.

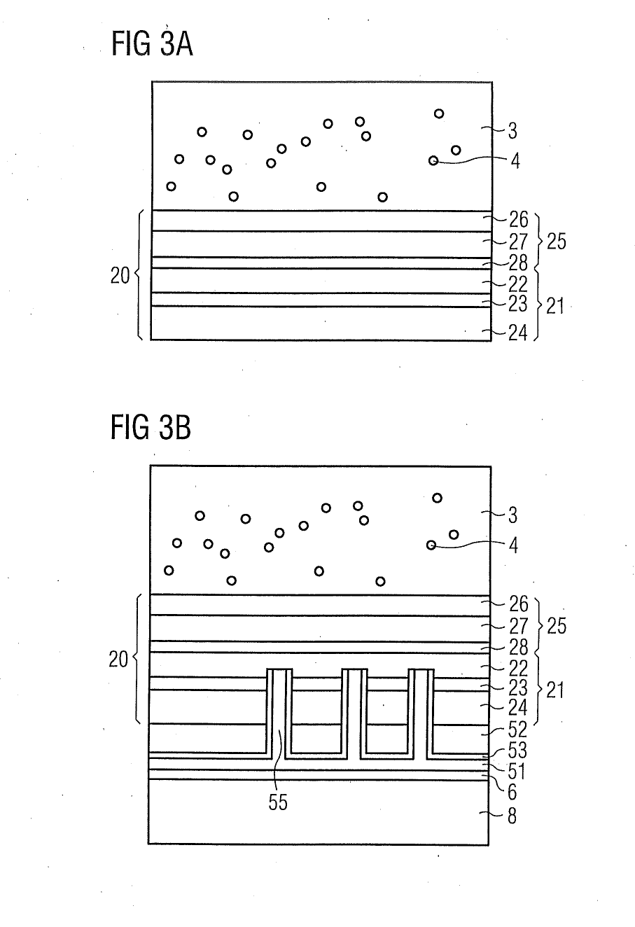

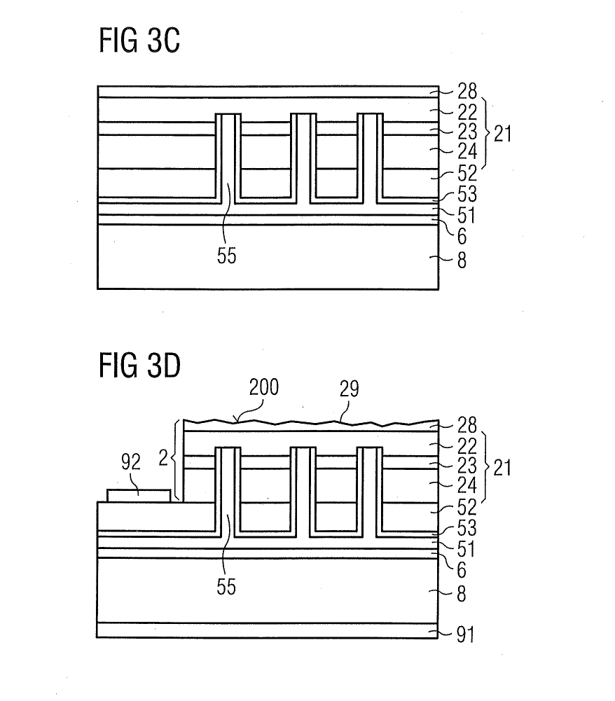

The second example of a method for producing a semiconductor component as shown in FIGS. 3A to 3D, differs from the first example in the further processing of the semiconductor layer sequence 20. Steps in the further processing or properties of the semiconductor component to be produced which are not explicitly described can be carried out or configured as in the first example. Production of the semiconductor layer sequence 20 itself can be effected as described in connection with FIG. 2A.

As illustrated in FIG. 3B, recesses 55 are formed in the semiconductor layer sequence 20 from the side facing away from the substrate 3, the recesses extending through the active region 23 into the first semiconductor layer 22.

In the recesses 55, the first semiconductor layer 22 is electrically contact-connected to a first connection layer 51.

The second semiconductor layer 24 is electrically contact-connected to a second connection layer 32. The second connection layer runs in regions between the semiconductor layer sequence 20 and the first connection layer 51. During operation, the second connection layer 32 is preferably furthermore provided to reflect radiation generated in the active region 23. In particular one of the materials mentioned in connection with the mirror layer is suitable for the second connection layer. The connection layers 51, 52 can be applied by vapor deposition or sputtering.

Before deposition of the first connection layer 51, an insulation layer 53 is applied, which covers the side areas of the recesses 55. An electrical short circuit of the active region 23 is thus prevented. Furthermore, the first insulation layer runs in regions between the first connection layer 51 and the second connection layer 52, such that these layers are electrically insulated from one another. By way of example, an oxide, for instance silicon oxide, or a nitride, for instance silicon nitride, is suitable for the insulation layer.

A carrier 8 is fixed by a connecting layer 6 on that side of the semiconductor layer sequence 20 which faces away from the substrate 3. The carrier and the connecting layer can be in connection with the first example described in FIGS. 2A to 2D.

As illustrated in FIG. 3C, the substrate 3, the nucleation and buffer layer 26 and the transition layer 27 are removed. The second connection layer 53 is subsequently exposed by the semiconductor layer sequence 20 being removed in regions.

A radiation exit area 200 of the semiconductor body 2 that faces away from the carrier 8 is provided with a structuring 29 to increase coupling-out efficiency. This can be effected before or after the second connection layer 52 is exposed. For external electrical contact-connection, a first contact 91 is formed, which is electrically conductively connected to the first semiconductor layer 22 via the first connection layer 51, and a second contact 92 is formed, which is electrically conductively connected to the second semiconductor layer 24 via the second connection layer 52.

The second contact 92 is spaced apart from the semiconductor body 2 in a lateral direction. The radiation exit area 200 is therefore free of an external electrical contact. The radiation power emerging from the radiation exit area can thus be increased.

In this example, the contacts 91, 92 are arranged on different sides of the carrier 8. However, the contacts can also be arranged on the same side.

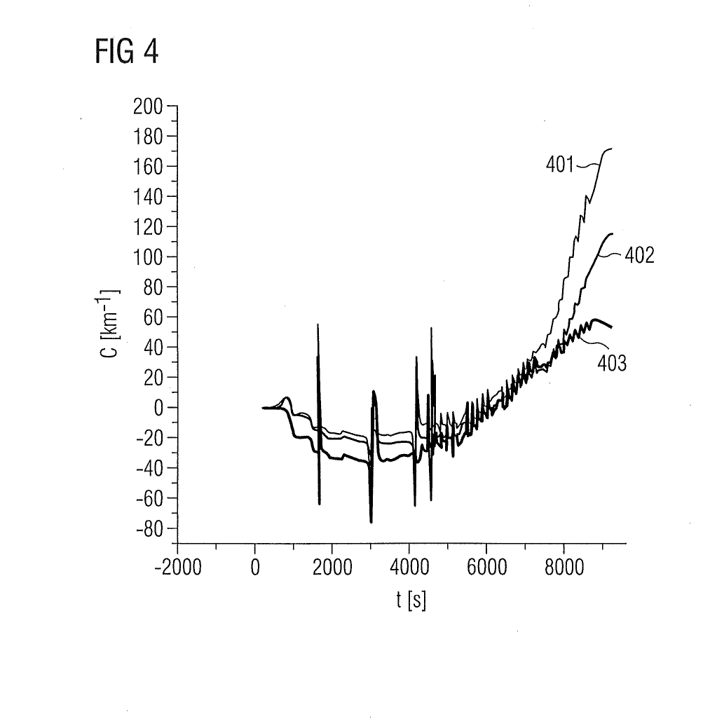

FIG. 4 shows results of measurements of the curvature C (in km⁻¹) as a function of deposition duration t (in s) for various substrates having impurities in different concentrations. During a deposition duration of approximately 9200 s as shown, semiconductor material having a thickness of approximately 4 μm is grown epitaxially in each case.

The curves 401 and 402 show the profile of the curvature C for two silicon substrates produced by the floating zone method and which differ in the concentration of the impurities. The curve 402 is assigned to a substrate distinguished by a nitrogen impurity increased in a targeted manner in comparison with the substrate associated with the curve 401. The concentration of the nitrogen impurity is approximately 10¹⁴ cm⁻³.

A curve 403 relates to a substrate deposited by the Czochralski method and having a concentration of the oxygen impurity of approximately 10¹⁷ cm⁻³.

All the curves exhibit an increase in the curvature in the illustrated range as the deposition duration increases. In the range 4500 s to 9000 s, the curve 403 exhibits a largely linear profile having a substantially constant gradient. In the case of the curves 401 and 402, by contrast, the gradient abruptly assumes a larger gradient in each case above 7000 s. For the curve 401, in this case the range in which the gradient is greater than in the linear range is shifted toward shorter times, that is to say toward smaller layer thicknesses. This behavior and also the larger gradient in comparison with the curve 402 show that the plastic deformation first commences earlier and second turns out to be greater in the case of the curve 401.

The measurements therefore show that the substrate having the highest concentration of impurities has the smallest curvature. By a targeted impurity, therefore, the curvature can be reduced such that deposition on the substrates can be effected particularly homogeneously in a lateral direction.

Our components, substrates and methods are not restricted by the description on the basis of the examples. Rather, this disclosure encompasses any novel feature and also any combination of features, which in particular includes any combination of features in the appended claims, even if the feature or combination itself is not explicitly specified in the claims or the examples.

1. A semiconductor component comprising:
a semiconductor body based on a nitridic compound semiconductor material, and
a substrate on which the semiconductor body is arranged, wherein impurities are formed in the substrate in a targeted manner.

2. The semiconductor component according to claim 1, wherein the impurities are provided to increase an upper yield point of the substrate.

3. The semiconductor component according to claim 1, wherein the substrate has a silicon surface.

4. The semiconductor component according to claim 3, wherein the surface is a (111) plane.

5. The semiconductor component according to claim 1, wherein the substrate is a silicon bulk substrate.

6. The semiconductor component according to claim 1, wherein the impurities are formed with a concentration of 1*10¹⁴ cm⁻³ to 1*10²⁰ cm⁻³ in the substrate.

7. The semiconductor component according to claim 1, wherein the impurities contain at least one of carbon, nitrogen, boron or oxygen.

8. The semiconductor component according to claim 1, wherein the semiconductor body has an active region provided to generate and/or receive radiation.

9. The semiconductor component according to claim 1, which is an electronic semiconductor component.

10. A substrate for deposition of nitridic compound semiconductor material, wherein impurities that increase its upper yield point are formed in a targeted manner in the substrate.

11. (canceled)

12. A method for producing a semiconductor layer sequence based on a nitridic compound semiconductor material comprising depositing the semiconductor layer sequence on a substrate, in which impurities (4) are formed in a targeted manner.

13. The method according to claim 12, wherein the substrate is removed or thinned at least in regions after deposition of the semiconductor layer sequence.

14. The method according to claim 12, wherein the semiconductor layer sequence is deposited in a compressively strained manner relative to the substrate at a deposition temperature.

15. (canceled)

16. A method for producing a semiconductor layer sequence based on a nitridic compound semiconductor material comprising depositing the semiconductor layer sequence on a substrate, wherein impurities are formed in a targeted manner, and the substrate is removed or thinned at least in regions after deposition of the semiconductor layer sequence.

17. The method according to claim 16, wherein the substrate has a silicon surface and the surface is a (111) plane, the semiconductor layer sequence being deposited on said silicon surface.
